(19) United States
(12) Patent Application Publication
(10) Pub. No.: US 2026/0130294 A1
(43) Pub. Date: May 7, 2026

(54) SEMICONDUCTOR PACKAGE

(71) Applicant: SAMSUNG ELECTRONICS CO., LTD., Suwon-si (KR)

(72) Inventors: Gongje Lee, Suwon-si (KR); Kyungdon Mun, Suwon-si (KR)

(73) Assignee: SAMSUNG ELECTRONICS CO., LTD., Suwon-si (KR)

(21) Appl. No.: 19/364,375

(22) Filed: Oct. 21, 2025

(30) Foreign Application Priority Data
Nov. 7, 2024 (KR) 10-2024-0156752

(51) Int. Cl. H01L 23/498; H01L 21/48; H01L 23/00; H01L 23/31; H01L 23/373; H01L 25/10

(52) U.S. Cl. CPC H10W 90/701; H10W 70/093; H10W 90/00; H10W 90/401; H10W 40/258; H10W 72/884; H10W 74/117; H10W 90/724; H10W 90/731; H10W 90/754

(57) ABSTRACT

Provided is a semiconductor package, including a lower redistribution layer structure including a lower redistribution layer, a lower semiconductor chip on the lower redistribution layer structure, the lower semiconductor chip connected to the lower redistribution layer, a sealing member on the lower semiconductor chip and the lower redistribution layer structure, a conductive post penetrating the sealing member, the conductive post connected to the lower redistribution layer, and an upper redistribution layer structure on an upper surface of the sealing member and an upper surface of the conductive post, the upper redistribution layer structure including an upper insulation layer and an upper redistribution layer, wherein a sidewall of the conductive post has a first uneven portion, and an upper surface of the conductive post has a second uneven portion, a roughness of the second uneven portion being different from a roughness of the first uneven portion.

### CROSS-REFERENCE TO RELATED APPLICATION

This application claims priority to Korean Patent Application No. 10-2024-0156752, filed on Nov. 7, 2024, in the Korean Intellectual Property Office KIPO, the disclosure of which is incorporated herein in its entirety by reference.

### BACKGROUND

### 1. Field

Embodiments of the present disclosure relate to a semiconductor package. Particularly, embodiments relate to a semiconductor package including a Fan Out Wafer Level Package (FOWPLP).

### 2. Description of Related Art

In the Fan Out Wafer Level Package (FOWLP) technology, conductive posts having a pillar shape may be used to electrically connect an upper chip and a lower chip. However, since an adhesion property between the conductive posts and a sealing member and an adhesion property between the conductive posts and an insulation layer are not sufficient good, a delamination between the conductive posts and a sealing member and a delamination between the conductive posts and the insulation layer may occur. Accordingly, a failure of reliability of the semiconductor package may occur.

### SUMMARY

One or more embodiments provide a semiconductor package having excellent characteristics.

According to an aspect of one or more embodiments, there is provided a semiconductor package, including a lower redistribution layer structure including a lower redistribution layer, a lower semiconductor chip on the lower redistribution layer structure, the lower semiconductor chip connected to the lower redistribution layer, a sealing member on the lower semiconductor chip and the lower redistribution layer structure, a conductive post penetrating the sealing member, the conductive post connected to the lower redistribution layer, and an upper redistribution layer structure on an upper surface of the sealing member and an upper surface of the conductive post, the upper redistribution layer structure including an upper insulation layer and an upper redistribution layer, wherein a sidewall of the conductive post has a first uneven portion, and the upper surface of the conductive post has a second uneven portion, a roughness of the second uneven portion being different from a roughness of the first uneven portion.

According to an aspect of one or more embodiments, there is provided a semiconductor package, including a lower redistribution layer structure including a lower insulation layer, a lower redistribution layer, and a bonding pad, a lower semiconductor chip on the lower redistribution layer structure, the lower semiconductor chip being connected to the lower redistribution layer, a sealing member on the lower semiconductor chip and the lower redistribution layer structure, a conductive post penetrating the sealing member and contacting the bonding pad of the lower redistribution layer, the conductive post being spaced apart from the lower semiconductor chip, an upper redistribution layer structure on an upper surface of the sealing member and an upper surface of the conductive post, and the upper redistribution layer structure including an upper insulation layer and an upper redistribution layer, the upper redistribution layer being connected to the conductive post, an upper semiconductor package on the upper redistribution layer structure, the upper semiconductor package being connected to the upper redistribution layer structure, and a heat dissipation structure on the upper redistribution layer structure, wherein a sidewall of the conductive post has a first uneven portion, and the upper surface of the conductive post has a second uneven portion, a roughness of the second uneven portion being different from a roughness of the first uneven portion.

According to still another aspect of one or more embodiments, there is provided a semiconductor package, including a lower redistribution layer structure including a lower insulation layer and a lower redistribution layer, an upper redistribution layer structure being spaced apart from the lower redistribution layer structure, the upper redistribution layer structure including an upper insulation layer and an upper redistribution layer, and a conductive post between the lower redistribution layer structure and the upper redistribution layer structure, wherein a sidewall of the conductive post has a first uneven portion, and the upper surface of the conductive post has a second uneven portion, a roughness of the second uneven portion being different from a roughness of the first uneven portion.

According to further still another aspect of one or more embodiments, there is provided method of manufacturing a semiconductor package, including forming a lower redistribution layer structure including a lower redistribution layer, forming a lower semiconductor chip on the lower redistribution layer structure, the lower semiconductor chip connected to the lower redistribution layer, forming a sealing member on the lower semiconductor chip and the lower redistribution layer structure, forming a conductive post penetrating the sealing member, the conductive post connected to the lower redistribution layer, forming an upper redistribution layer structure on an upper surface of the sealing member and an upper surface of the conductive post, the upper redistribution layer structure including an upper insulation layer and an upper redistribution layer, wherein a sidewall of the conductive post has a first uneven portion, and the upper surface of the conductive post has a second uneven portion, a roughness of the second uneven portion being different from a roughness of the first uneven portion.

The method may further include forming an upper semiconductor package on the upper redistribution layer structure, the upper semiconductor package being connected to the upper redistribution layer structure, and forming a heat dissipation structure on the upper redistribution layer structure.

### BRIEF DESCRIPTION OF DRAWINGS

Embodiments will be more clearly understood from the following detailed description taken in conjunction with the accompanying drawings in which:

FIG. 1 is a cross-sectional view illustrating a semiconductor package according to one or more embodiments;

FIG. 2 is an enlarged cross-sectional view of a portion A of FIG. 1;

FIG. 3 is a plan view illustrating a semiconductor package according to one or

more embodiments;

FIGS. 4, 5, 6, 7, 8, 9, 10, 11, 12, 13, 14, 15, 16, and 17 are cross-sectional views illustrating a method for manufacturing a semiconductor package according to one or more embodiments;

FIG. 18 is a cross-sectional view illustrating a semiconductor package according to one or more other embodiments;

FIG. 19 is a plan view illustrating a semiconductor package according to one or more other embodiments;

FIG. 20 is a plan view illustrating a semiconductor package according to some one or more other embodiments; and

FIG. 21 is a cross-sectional view illustrating a semiconductor package according to one or more other embodiments.

### DETAILED DESCRIPTION

Hereinafter, various embodiments will be described in detail with reference to the accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

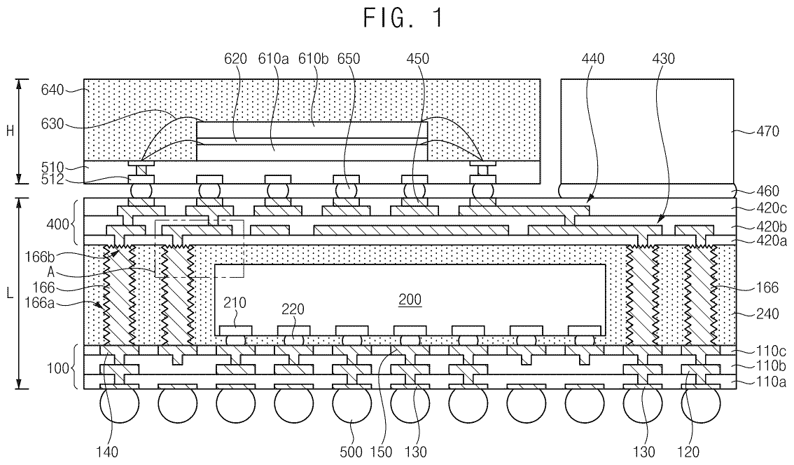

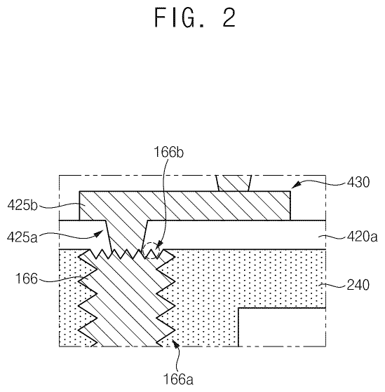

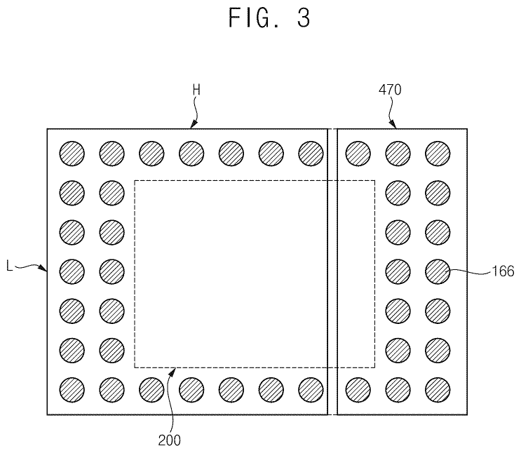

FIG. 1 is a cross-sectional view illustrating a semiconductor package according to one or more embodiments. FIG. 2 is an enlarged cross-sectional view of a portion A of FIG. 1. FIG. 3 is a plan view illustrating a semiconductor package according to one or more embodiments.

Referring to FIGS. 1 to 3, the semiconductor package may include a lower package L, an upper package H and a heat dissipation structure 470 disposed on the lower package L.

The lower package L may include a lower redistribution layer structure 100, a lower semiconductor chip 200 disposed on the lower redistribution layer structure 100, a first sealing member 240 provided on or covering the lower semiconductor chip 200 on an upper surface of the lower redistribution layer structure 100, conductive posts 166 passing through the first sealing member 240, and an upper redistribution layer structure 400 disposed on the lower semiconductor chip 200 and the first sealing member 240.

In one or more embodiments, the lower package L may be a fan-out package in which the lower redistribution layer structure 100 may extend to the first sealing member 240 provided on or covering an outer side of the lower semiconductor chip 200.

The lower package L may operate as a system in package (SIP). For example, one or more lower semiconductor chips 200 may be disposed on the lower redistribution layer structure 100. The lower semiconductor chip 200 may include, for example, a logic chip including logic circuits. The logic chip may be a controller that controls memory chips. In one or more embodiments, the lower semiconductor chip 200 may be a processor chip such as an application-specific integrated circuit (ASIC) or an application processor (AP) as a host such as a central processing unit (CPU), a graphical processing unit (GPU), or a system-on-a-chip (SOC).

The lower redistribution layer structure 100 may include lower insulation layers 110a, 110b and 110c, lower redistribution layers 120, a lower pad 130, a first bonding pad 140, and a second bonding pad 150. The lower semiconductor chip 200 electrically connected to the lower redistribution layers 120 may be disposed on the lower redistribution layer structure 100. The lower redistribution layer structure 100 may operate as a front redistribution layer that is disposed facing a front surface of the lower semiconductor chip 200. Therefore, the lower redistribution layer structure 100 may be the front redistribution layer (FRDL) of a fan-out package.

In one or more embodiments, the lower redistribution layer structure 100 may include a first lower insulation layer 110a, a second lower insulation layer 110b and a third lower insulation layer 110c. The first bonding pad 140 and the second bonding pad 150 may be arranged on the third lower insulation layer 110c located at the top of the lower redistribution layer structure 100. A plurality of first bonding pads 140 may be pads for contacting the conductive posts 166, and a plurality of second bonding pads 150 may be pads for electrically connecting the lower semiconductor chip 200. In addition, the lower redistribution layers 120 may be arranged in the lower insulation layer (e.g., the second lower insulation layer 110b) between an uppermost lower insulation layer (e.g., the third lower insulation layer 110c) and a lowermost lower insulation layer (e.g., the first lower insulation layer 110a). The lower redistribution layers 120 may have a shape in which a plurality of layers are stacked.

The first to third lower insulation layers 110a, 110b and 110c may include, e.g., a polymer, a dielectric layer, etc. For example, the first to third lower insulation layers 110a, 110b and 110c may include a photosensitive insulation layer such as a photo imageable dielectric (PID).

The lower redistribution layers 120 may include, e.g., copper (Cu), aluminum (Al), tin (Sn), nickel (Ni), gold (Au), silver (Ag), platinum (Pt), or an alloy thereof. In one or more embodiments, the lower redistribution layers 120 may include a via contact and a wiring line.

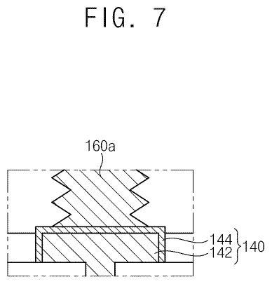

Each of the first and second bonding pads 140 and 150 may include, e.g., copper (Cu), aluminum (Al), tin (Sn), nickel (Ni), gold (Au), silver (Ag), platinum (Pt), or an alloy thereof. The first and second bonding pads 140 and 150 may include a pad pattern 142 (referred to FIG. 7) and a capping metal pattern 144 (referred to FIG. 7). The capping metal pattern 144 may be provided on and cover a surface of the pad pattern 142. The pad pattern 142 may include, e.g., copper, and the capping metal pattern 144 may include, e.g., gold (Au), silver (Ag), or nickel (Ni).

The upper surfaces of the first and second bonding pads 140 and 150 may not be covered by the third lower insulation layer 110c. The upper surfaces of the first and second bonding pads 140 and 150 may be exposed by the third lower insulation layer 110c.

A number and an arrangement, etc. of the lower insulation layers 110a, 110b and 110c and the lower redistribution layers 120 included in the lower redistribution layer structure 100 are described as examples, and it will be understood that embodiments are not limited thereto.

In one or more embodiments, a plurality of chip pads 210 may be on a first surface (i.e., the active surface) of the lower semiconductor chip 200. The lower semiconductor chip 200 may be mounted on the lower redistribution layer structure 100 so that the first surface on which the chip pads 210 are formed may face the lower redistribution layer structure 100.

The lower semiconductor chip 200 may be mounted on the lower redistribution layer structure 100 with conductive bumps 220 between the lower semiconductor chip 200 and the lower redistribution layer structure 100. Each of the conductive bumps 220 may be interposed between the second bonding pad 150 of the lower redistribution layer structure 100 and the chip pad 210 of the lower semiconductor chip 200, and thus the lower semiconductor chip 200 and the lower redistribution layers 120 may be electrically connected by the conductive bumps 220. For example, the conductive bump 220 may include a pillar bump on the chip pad 210 of the lower semiconductor chip 200 and a solder bump on the pillar bump.

In one or more embodiments, the lower semiconductor chip 200 may be positioned at a central portion of the upper surface of the lower redistribution layer structure 100. However, the position of the lower semiconductor chip 200 is not limited thereto. The position of the lower semiconductor chip 200 may be variously changed according to an arrangement of the conductive posts 166 described below.

Although only a few chip pads 210 are illustrated in the drawings, the structure and the arrangement of the chip pads are provided as examples, and it will be understood that embodiments are not limited thereto. In addition, one lower semiconductor chip 200 on the lower redistribution layer structure 100 is illustrated in the drawings, but it is not limited thereto. For example, a plurality of lower semiconductor chips 200 may be stacked on the lower redistribution layer structure 100.

The conductive posts 166 may contact the first bonding pads 140, respectively, and may extend upward from the upper surface of the lower redistribution layer structure 100. The conductive posts 166 may be spaced apart from the lower semiconductor chip 200. The upper surfaces of the conductive posts 166 may be at a higher level than a level of an upper surface of the lower semiconductor chip 200 in a vertical direction perpendicular to the upper surface of the lower semiconductor chip 200.

In one or more embodiments, the conductive posts 166 may extend from the upper surface of the lower redistribution layer structure 100 in the vertical direction. In some one or more embodiments, the conductive posts 166 may extend obliquely at an angle from the upper surface of the lower redistribution layer structure 100.

The sidewalls of the conductive posts 166 may have a roughness, and the upper surface may have a roughness. The sidewall of each of the conductive posts 166 may have first uneven portion 166a, and the upper surface of each of the conductive posts 166 may have a second uneven portion 166b. For example, the first uneven portion 166a may correspond to the sidewall of each of the conductive posts 166, and the second uneven portion 166b may correspond to the upper surface of each of the conductive posts 166. The sidewalls of the conductive posts 166 may have a first arithmetic mean roughness (Ra). In one or more embodiments, the first arithmetic mean roughness may be in a range of about 0.2 μm to about 0.25 μm. The upper surfaces of the conductive posts 166 may have a second arithmetic mean roughness less than the first arithmetic mean roughness. In one or more embodiments, the second arithmetic mean roughness may be in a range of about 0.05 μm to about 0.1 μm.

The roughness of the sidewalls of the conductive posts 166 may be provided to improve an adhesion property between the first sealing member 240 and the sidewalls of the conductive posts 166. When the first arithmetic mean roughness of the sidewalls of the conductive posts 166 is less than 0.2 μm, an effect of preventing interfacial delamination between the between the first sealing member 240 and the sidewalls of the conductive posts 166 may be decreased. When the first arithmetic mean roughness of the sidewalls of the conductive posts 166 is greater than 0.25 μm, an irregularity of the sidewalls of the conductive posts 166 may increase, and thus uniformity of electrical characteristics of the semiconductor package may be decreased.

The roughness of the upper surfaces of the conductive posts 166 may be provided to improve an adhesion property between a first upper insulation layer 420a located at the lowermost portion of the upper redistribution layer structure 400 and the upper surfaces of the conductive posts 166 and to prevent cracks of the first upper insulation layer 420a. When the second arithmetic mean roughness of the upper surfaces of the conductive posts 166 is less than 0.05 μm, an effect of preventing interfacial delamination between the first upper insulation layer 420a and the upper surfaces of the conductive posts 166 may be decreased. When the second arithmetic mean roughness of the upper surface of the conductive post 166 is greater than 0.1 μm, light scattering may occur in a photolithography process for forming a via hole in the first upper insulation layer 420a in process for forming the upper redistribution layer structure 400. Therefore, a defect of the upper redistribution layer structure 400 may occur.

The first sealing member 240 may be provided on and cover the lower semiconductor chip 200 on the upper surface of the lower redistribution layer structure 100.

In one or more embodiments, as shown in FIG. 1, the first sealing member 240 may be provided on or may cover a lower surface of the lower semiconductor chip 200, sidewalls of the lower semiconductor chip 200, and the upper surface of the lower semiconductor chip 200. In this case, the upper surface of the lower semiconductor chip 200 may be covered by the first sealing member 240.

In some one or more embodiments, in the semiconductor package 10a, the first sealing member 240 may be provided on or may cover the lower surface and the sidewalls of the lower semiconductor chip 200. In this case, the upper surface of the lower semiconductor chip 200 may be exposed by the first sealing member 240. The upper surfaces of the conductive posts 166 may be coplanar with the uppermost surface of the lower semiconductor chip 200.

The upper surfaces of the conductive posts 166 may not be covered by the first sealing member 240. For example, the upper surfaces of the conductive posts 166 may be exposed by the first sealing member. The first sealing member 240 may be provided on and cover entire sidewalls of the conductive posts 166.

The first sealing member 240 may include, e.g., an epoxy mold compound (EMC).

The conductive posts 166 may pass through the first sealing member 240. The entire sidewalls of the conductive posts 166 may contact the first sealing member 240. The first uneven portion of the conductive posts 166 may contact the first sealing member 240.

Since the sidewalls of the conductive posts 166 contacting the first sealing member 240 has the first arithmetic mean roughness, the adhesion property between the first sealing member 240 and the sidewalls of the conductive posts 166 may be improved compared to a case where the sidewalls of the conductive posts does not have a roughness. Accordingly, the delamination between the sidewalls of the conductive posts 166 and the first sealing member 240 may be decreased.

In one or more embodiments, as shown in FIG. 3, the conductive posts 166 may be spaced apart from each other, and the conductive posts 166 may be arranged on a side of and to surround the lower semiconductor chip 200.

The conductive posts 166 may pass through the first sealing member 240, and the conductive posts 166 may operate as an electrical connection passage between the upper semiconductor chips 610a and 610b and the lower semiconductor chip 200. Each of the conductive posts 166 may be a through mold via (TMV) penetrating the first sealing member 240. The conductive posts 166 may be arranged in a fan-out region which is an outside region of a region of the lower semiconductor chip 200.

The conductive post 166 may include a metal. The conductive post 166 may include, e.g., copper (Cu).

The upper redistribution layer structure 400 may be arranged on the lower semiconductor chip 200 and the first sealing member 240. The upper redistribution layer structure 400 may include upper insulation layers 420a, 420b and 420c, upper redistribution layers 430 and 440, and a third bonding pad 450.

The upper redistribution layer structure 400 may be provided on the first sealing member 240, and the upper redistribution layer structure 400 may operate as backside redistribution layers. Accordingly, the upper redistribution layer structure 400 may be a backside redistribution layer BRDL of the fan out package. The upper redistribution layer structure 400 and the lower redistribution layer structure 100 may be electrically connected by the conductive posts 166.

In one or more embodiments, the upper redistribution layer structure 400 may include a first upper insulation layer 420a, a second upper insulation layer 420b and a third upper insulation layer 420c, and a first upper redistribution layer 430 and a second upper redistribution layer 440 disposed within the first to third upper insulation layers 420a, 420b and 420c. The third bonding pad 450 may be arranged on the third upper insulation layer 420c located at the top of the upper redistribution layer structure 400.

The first to third upper insulation layers 420a, 420b and 420c may include a polymer, a dielectric layer, or the like. For example, the first to third upper insulation layers 420a, 420b and 420c may include a photosensitive insulation layer such as a photo imageable dielectric (PID).

The upper redistribution layers 430 and 440 may include, e.g., copper (Cu), aluminum (Al), tin (Sn), nickel (Ni), gold (Au), silver (Ag), platinum (Pt), or an alloy thereof.

In one or more embodiments, each of the upper redistribution layers 430 and 440 may include a via contact and a wiring line.

The first upper insulation layer 420a may contact the upper surfaces of the conductive posts 166 and the upper surface of the first sealing member 240. The first upper redistribution layer 430 may include a first via contact penetrating the first upper insulation layer 420a and contacting at least a portion of the upper surface of the conductive post 166, and a first wiring line disposed on the first upper insulation layer 420a.

An area of a bottom of the first via contact 425a contacting the conductive post 166 may be less than an area of the upper surface of the conductive post 166. In one or more embodiments, a portion of the upper surface of the conductive post 166 may be exposed outside a portion of the first via contact 425a contacting the conductive post 166. A portion of the upper surface of the conductive post 166 that is exposed by and does not contact the first via contact 425a may contact the first upper insulation layer 420a.

For example, a portion of the upper surface of the conductive post 166 may contact the first via contact disposed at a lowermost portion of the upper redistribution layer structure 400, and a remaining portion of the upper surface of the conductive post 166 may contact the first upper insulation layer 420a, which is a lowermost insulation layer of the upper redistribution layer structure 400.

Since the upper surfaces of the conductive posts 166 contacting the first upper insulation layer 420a has the second arithmetic mean roughness, the adhesion property between the first upper insulation layer 420a and the upper surfaces of the conductive posts 166 may be improved compared to the case where the upper surfaces of the conductive posts 166 is flat and does not have roughness. Accordingly, the delamination between the upper surfaces of the conductive posts 166 and the first upper insulation layer 420a may be decreased. In one or more embodiments, the first via contact contacting the upper surface of the conductive post 166 may include a metal the same as a material of the conductive post 166. In this case, the adhesion property between the first via contact and the upper surface of the conductive post 166 may be improved. The first via contact may include, e.g., copper. The third bonding pad 450 may be arranged within the third upper insulation layer 420c located at the top of the upper redistribution layer structure 400.

The third bonding pad 450 may be arranged to face the upper package H in the vertical direction. The third bonding pad 450 may be electrically connected to the second upper redistribution layer 440. The third upper insulation layer 420c may be disposed between the third bonding pads 450. The third upper insulation layer 420c may not cover and expose an upper surface of the third bonding pad 450.

The third bonding pad 450 may be provided to electrically connect the lower package L and the upper package H.

The third bonding pad 450 may include a metal. In one or more embodiments, the third bonding pad 450 may include copper (Cu), aluminum (Al), tin (Sn), nickel (Ni), gold (Au), silver (Ag), platinum (Pt), or an alloy thereof. For example, the third bonding pad 450 may include copper, and a surface of the copper may be covered with gold, silver, or nickel by a surface treatment.

The upper package H may be stacked on the lower package L.

In one or more embodiments, the upper package H may include a package substrate 510, at least one upper semiconductor chip 610a and 610b mounted on the package substrate 510, and a second sealing member 640 covering the upper semiconductor chip 610a and 610b on the upper semiconductor chip 610a and 610b and the package substrate 510. The upper package H may further include bonding wires 630 for connecting the upper semiconductor chips 610a and 610b and the package substrate 510.

In one or more embodiments, in the upper package H, a plurality of upper semiconductor chips 610a and 610b may be sequentially stacked on the package substrate 510 using an adhesive member 620. The upper chip pads of the upper semiconductor chips 610a and 610b and the fourth bonding pads 512 arranged on the upper surface of the package substrate 510 may be connected by the bonding wires 630.

Although the upper package H includes two semiconductor chips mounted by a wire bonding process in FIG. 1, it will be understood that the number of semiconductor chips and the mounting process of semiconductor chips in the upper package H not limited thereto.

A conductive connection member 650 may be disposed on the third bonding pad 450 of the lower package L, and the upper package H may be bonded on the conductive connection member 650. The conductive connection members 650 may include solder balls, conductive bumps, etc. The conductive connection member 650 may be disposed between the third bonding pad 450 of the upper redistribution layer structure 400 and the fourth bonding pad 512 of the package substrate 510. Accordingly, the lower package L and the upper package H may be electrically connected to each other by the conductive connection members 650.

The heat dissipation structure 470 may be stacked on the lower package L in the vertical direction and adjacent to the upper package H in a horizontal direction parallel to an upper surface of the lower package L. The heat dissipation structure 470 may be referred to as a heat path block (HPB). A thermal interface material layer 460 may be interposed between the lower package L and the heat dissipation structure 470, so that the heat dissipation structure 470 may be adhered to the lower package L by the thermal interface material layer 460. The heat dissipation structure 470 may be spaced apart from the lower package L in the vertical direction by the thermal interface material layer 460. In addition, the heat dissipation structure 470 may be spaced apart from the upper package H in lateral direction.

In one or more embodiments, the heat dissipation structure 470 may extend along one edge of the lower package L in a first direction.

In some one or more embodiments, the heat dissipation structure 470 may extend along two edges of the lower package L in the first direction and a second direction perpendicular to the first direction. In this case, the heat dissipation structure 470 may have an L-shape.

However, embodiments are not limited thereto, and for example, the heat dissipation structure 470 may have a square ring shape surrounding the lower package L.

The heat dissipation structure 470 may be provided to dissipate heat generated during operating the lower semiconductor chip 200 included in the lower package L to outside. The heat dissipation structure 470 may include a metal having relatively high thermal conductivity, e.g., copper. A position of the heat dissipation structure 470 is not limited, and the heat dissipation structure 470 may be disposed in a remaining space after the upper semiconductor chip 610a and 610b is mounted on the lower package L.

External connection members 500 electrically connected to the lower redistribution layers 120 may be arranged on the lower pads 130 of the lower redistribution layer structure 100, respectively. The external connection members 500 may include, e.g., solder balls, conductive bumps, etc.

As described above, the adhesion property between the sidewalls of the conductive posts 166 and the first sealing member 240 may be increased, and thus the delamination between the sidewalls of the conductive posts 166 and the first sealing member 240 may be decreased. In addition, the adhesion property between the upper surfaces of the conductive posts 166 and the first upper insulation layer 420a may be increased. Accordingly, the delamination between the upper surfaces of the conductive posts 166 and the first upper insulation layer 420a and the crack of the first upper insulation layer 420a may be decreased. Therefore, the semiconductor package may have improved reliability.

Hereinafter, a method for manufacturing the semiconductor package of FIG. 1 is described.

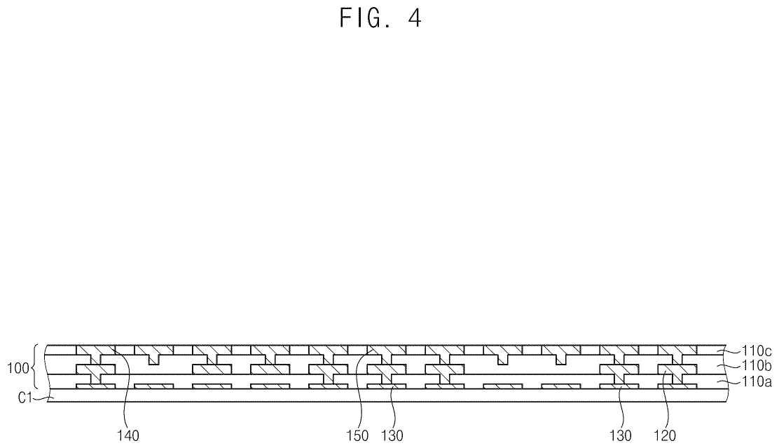

FIGS. 4 to 17 are cross-sectional views illustrating a method for manufacturing a semiconductor package according to one or more embodiments.

FIGS. 7, 11, and 13 are enlarged cross-sectional views of a portion of a semiconductor package according to one or more embodiments.

Referring to FIG. 4, a lower redistribution layer structure 100 may be formed on a carrier substrate C1. The lower redistribution layer structure 100 may include lower insulation layers 110a, 110b and 110c, lower redistribution layers 120, lower pads 130, first bonding pads 140, and second bonding pads 150.

The carrier substrate C1 may be a base substrate for arranging a plurality of semiconductor chips on the lower redistribution layer structure 100 and forming a sealing member covering the plurality of semiconductor chips. In one or more embodiments, the carrier substrate C1 may have a shape corresponding to a wafer on which semiconductor processes are performed. In one or more embodiments, the carrier substrate C1 may include a silicon substrate, a glass substrate, a plate of non-metal or metal, etc.

The carrier substrate C1 may include package regions where the semiconductor chips are mounted and a cutting region surrounding and adjacent to the package regions. The lower redistribution layer structure 100 and the first sealing member 240 formed on the carrier substrate C1 may be cut along the cutting region, so that the lower redistribution layer structure 100 and the first sealing member 240 may be individualized.

First, a release layer may be formed on the carrier substrate C1, and lower pads 130 are formed on the release layer. A first lower insulation layer 110a covering the lower pads 130 may be formed on the release layer. Next, the first lower insulation layer 110a may be patterned to form first openings exposing the lower pads 130.

The first lower insulation layer 110a may include, e.g., a polymer, a dielectric layer, etc. For example, the first lower insulation layer 110a may include a photosensitive insulation layer such as a photo imageable dielectric (PID).

The first lower insulation layer 110a may be formed by, e.g., a vapor deposition process or a spin coating process. The lower pads 130 may be formed by, e.g., an electroplating process, an electroless plating process, a vapor deposition process, etc.

The lower redistribution layers 120 may be formed on the first lower insulation layer 110a, and the lower redistribution layers 120 may be directly contact the lower pads 130 through the first opening. The lower redistribution layers 120 may be formed by forming a seed layer on a portion of the first lower insulation layer 110a and in the first openings, patterning the seed layer, and then performing an electroplating process on the seed layer.

For example, the lower redistribution layers 120 may include aluminum (Al), copper (Cu), tin (Sn), nickel (Ni), gold (Au), platinum (Pt), or an alloy thereof.

Next, a second lower insulation layer 110b provided on and covering the lower redistribution layers 120 may be formed on the first lower insulation layer 110a, and then the second lower insulation layer 110b may be patterned to form second openings exposing the lower redistribution layers 120. First bonding pads 140 and second bonding pads 150 may be formed on the second lower insulation layer 110b. The first and second bonding pads 140 and 150 may directly contact the lower redistribution layers 120 through the second openings. The first bonding pads 140 may be arranged in regions for forming the conductive posts 166. The second bonding pads 150 may be arranged to overlap a region for disposing a lower semiconductor chip in the vertical direction.

A third lower insulation layer 110c may be formed on the second lower insulation layer 110b to fill a space between the first and second bonding pads 140 and 150.

Since the first and second bonding pads 140 and 150 are formed by the same process, the first and second bonding pads 140 and 150 may include the same metal material.

In one or more embodiments, the first and second bonding pads 140 and 150 may have a structure in which a plurality of metal materials are stacked. The first and second bonding pads 140 and 150 may include a pad pattern (142, referred to FIG. 7) and a capping metal pattern 144 (referred to FIG. 7). The capping metal pattern 144 may be provided on and cover an upper surface and sidewalls of the pad pattern 142. The capping metal pattern 144 may include a first metal material different from a material of the pad pattern. For example, in the first and second bonding pads 140 and 150, the pad pattern 142 may include copper (Cu), and the capping metal pattern 144 may include gold (Au). The capping metal pattern 144 may be formed by a surface treatment.

Accordingly, a lower redistribution layer structure 100 including the first to third lower insulation layers 110a, 110b and 110c, the lower pad 130, the first and second bonding pads 140 and 150, and the lower redistribution layer 120 may be formed on the carrier substrate C1.

The lower redistribution layer structure 100 may operate as a front redistribution layer FRDL of a fan out package. The first and second bonding pads 140 and 150 may be exposed by an upper surface of the lower redistribution layer structure 100.

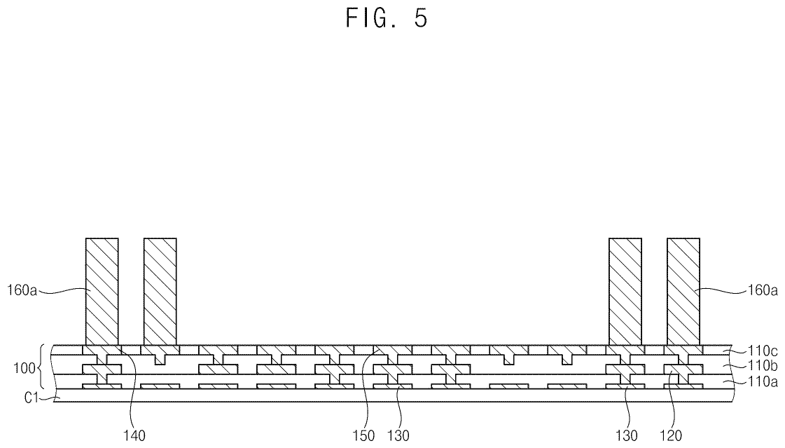

Referring to FIG. 5, first preliminary conductive posts 160a may be formed on the upper surface of the lower redistribution layer structure 100.

In one or more embodiments, a photoresist layer may be formed on the upper surface of the lower redistribution layer structure 100, and an exposure process may be performed on the photoresist layer to form a photoresist pattern having openings for forming first preliminary conductive posts 160a on the lower redistribution layer structure 100. At least a portion of the first bonding pad 140 may be exposed by the openings of the photoresist pattern.

A conductive material may be filled into the openings of the photoresist pattern to form the first preliminary conductive posts 160a. The photoresist pattern may be removed by a stripping process. In one or more embodiments, the first preliminary conductive posts 160a may be formed by a plating process.

The first preliminary conductive posts 160a may include a second metal material different from the first metal material. The first preliminary conductive posts 160a may include, e.g., copper.

The first preliminary conductive posts 160a may contact an upper surface of the first bonding pad 140, and may extend in the vertical direction perpendicular to the upper surface of the first bonding pad 140. The first preliminary conductive posts 160a may be electrically connected to the lower redistribution layers 120 included in the lower redistribution layer structure 100. The first preliminary conductive posts 160a may be arranged in a fan-out area, which is an outside of an area where the semiconductor chip (die) is disposed.

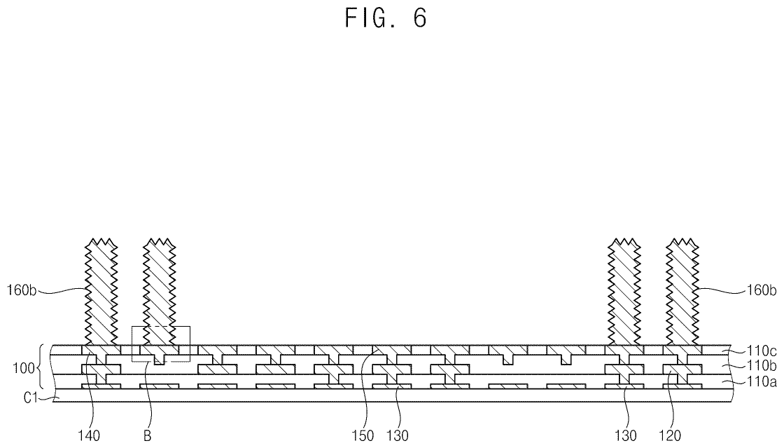

Referring to FIGS. 6 and 7, exposed surfaces of the first preliminary conductive posts 160a may be etched at a very low etching rate using an etchant including an organic acid, so that second preliminary conductive posts 160b having a surface roughness greater than a surface roughness of the first preliminary conductive posts 160a may be formed. Sidewalls and upper surfaces of the second preliminary conductive posts 160b may have unevenness and roughness. The sidewalls and upper surfaces of the second preliminary conductive posts 160b may have a first arithmetic mean roughness Ra. In one or more embodiments, the first arithmetic mean roughness may be in a range of about 0.2 μm to about 0.25 μm. When the first arithmetic mean roughness is less than about 0.2 μm, an effect of preventing surface delamination may be relatively small. In addition, when the first arithmetic mean roughness is greater than 0.25 μm, uniformity of electrical characteristics may be decreased due to a surface irregularity.

As the capping metal pattern 144 including the first metal material at surfaces of the first and second bonding pads 140 and 150 is exposed, the surfaces of the first and second bonding pads 140 and 150 may not be etched in the etching process. Accordingly, the unevenness may not occur on the surfaces of the first and second bonding pads 140 and 150.

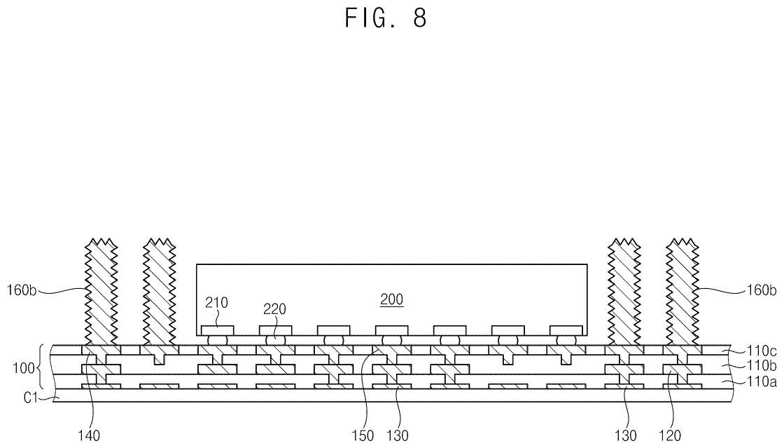

Referring to FIG. 8, a lower semiconductor chip (die) 200 may be mounted within a fan-in region of the lower redistribution layer structure 100.

The lower semiconductor chip 200 may be disposed so that a front surface, i.e., an active surface, on which chip pads 210 are formed, may face the lower redistribution layer structure 100. The chip pads 210 of the lower semiconductor chip 200 may be electrically connected to the first bonding pads 140 of the lower redistribution layer structure 100 by conductive bumps 220. Accordingly, the lower semiconductor chip 200 may be electrically connected to the lower redistribution layers 120 of the lower redistribution layer structure 100 by the conductive bumps 220. For example, the conductive bump 220 may include a micro bump (uBump).

The lower semiconductor chip 200 may be a logic chip including logic circuits. The logic chip may be a controller that controls memory chips. In one or more embodiments, the lower semiconductor chip 200 may be a processor chip such as an ASIC, an AP as a host such as a CPU, a GPU, or a SOC.

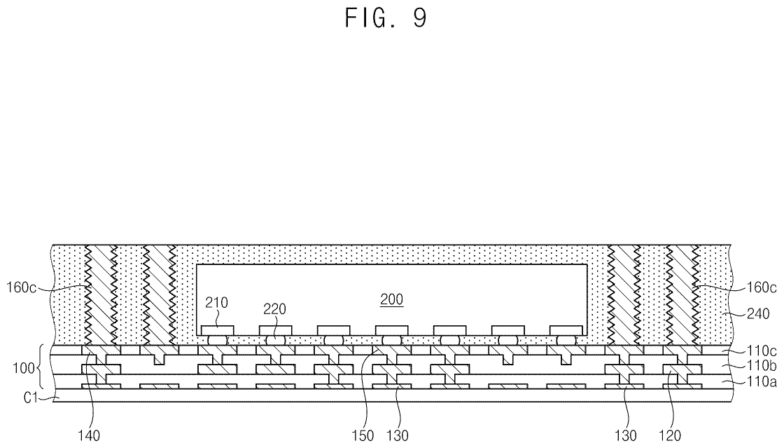

Referring to FIG. 9, a sealing member provided on and covering the lower semiconductor chip 200 and a plurality of second preliminary conductive posts 160b may be formed on the lower redistribution layer structure 100.

The sealing member may fill a space between the lower redistribution layer structure 100 and the lower semiconductor chip 200, and may be provided on and cover an upper surface of the lower semiconductor chip 200 and the upper surfaces of the plurality of second preliminary conductive posts 160b. For example, the sealing member may include an epoxy mold compound EMC. The sealing member may include UV resin, polyurethane resin, silicone resin, silica filler, etc.

The sealing member may be formed by a molding process, a screen printing process, a lamination process, etc.

The sealing member may directly contact the sidewalls of the second preliminary conductive posts 160b. Thermal expansion coefficients of the second preliminary conductive posts 160b and the sealing member may be different from each other, such that stress may significantly occur at a contact area between the second preliminary conductive posts 160b and the sealing member. Accordingly, the adhesive property between the second preliminary conductive posts 160b and the sealing member may not be effective. However, since the sidewalls of the second preliminary conductive posts 160b have the unevenness and a roughness, the adhesion property between the sidewalls of the second preliminary conductive posts 160b and the sealing member may be improved, and thus the delamination between the sidewalls of the second preliminary conductive posts 160b and the sealing member may be reduced.

An upper portion of the sealing member may be partially removed to form a first sealing member 240 exposing the upper surfaces of a plurality of second preliminary conductive posts 160b. The partially removing of the sealing member may include a grinding process. In the grinding process, the upper portions of the second preliminary conductive posts 160b may also be partially removed to form third preliminary conductive posts 160c having flat and uniform upper surface.

In one or more embodiments, the first sealing member 240 may be provided on and cover a lower portion, the sidewall, and the upper surface of the lower semiconductor chip 200.

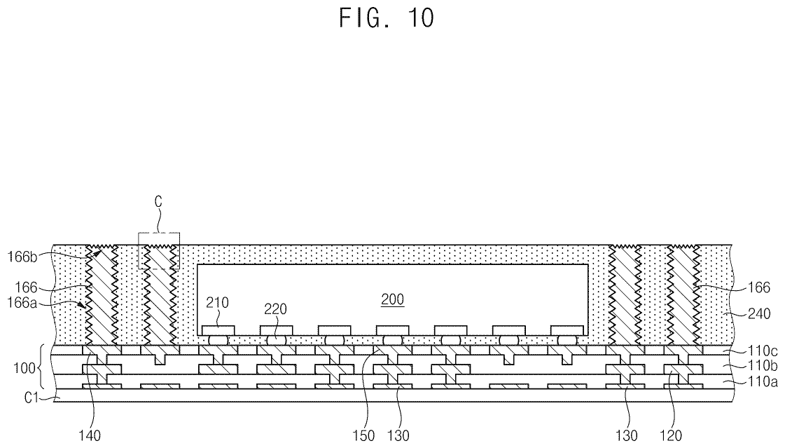

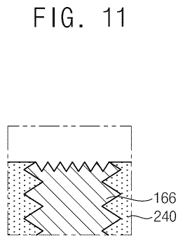

Referring to FIGS. 10 and 11, upper surfaces of the third preliminary conductive posts 160c exposed by the first sealing member 240 may be etched at a very low etching rate using an etchant including an organic acid to form conductive posts 166.

Therefore, exposed upper surfaces of the conductive posts 166 may have a second uneven portion 166b. A roughness of the exposed upper surfaces of the conductive posts 166 may be greater than a roughness of the upper surface of the third preliminary conductive posts 160c. The roughness of the exposed upper surfaces of the conductive posts 166 may be a second arithmetic mean roughness Ra less than the first arithmetic mean roughness Ra.

The sidewall of each of the conductive posts 166 may have the first uneven portion 166a. The sidewalls of the conductive posts 166 may be correspond to the first uneven portion 166a. The roughness of the sidewalls of the conductive posts 166 may have the first arithmetic mean roughness.

In one or more embodiments, the second arithmetic mean roughness may be in the range of about 0.05 μm to about 0.1 μm. When the second arithmetic mean roughness is less than 0.05 μm, an effect of preventing surface delamination may be relatively small. In addition, when the second arithmetic mean roughness is greater than 0.1 μm, a defect may occur due to light scattering in a photo process for subsequently forming via hole, i.e., the fourth opening.

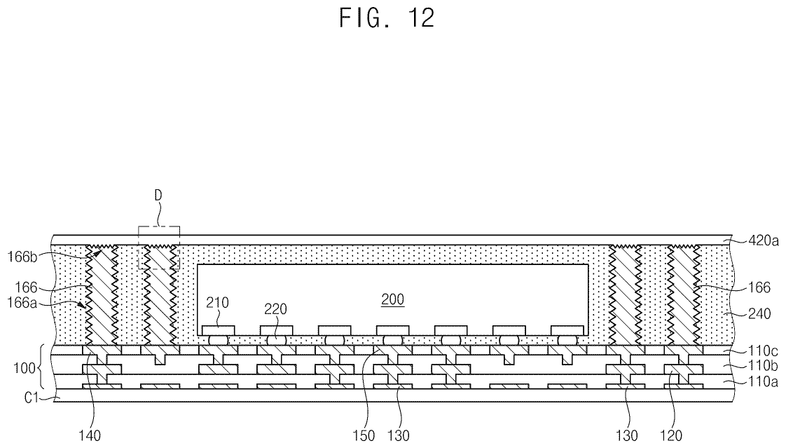

As illustrated in FIGS. 12 to 15, an upper redistribution layer structure 400 may be formed on upper surfaces of the first sealing member 240 and the conductive posts 166. The upper redistribution layer structure 400 may include upper redistribution layers 430 and 440, upper insulation layers 420a, 420b, and 420c, and a third bonding pad 450.

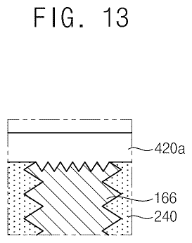

First, referring to FIGS. 12 and 13, a first upper insulation layer 420a may be formed on the upper surface of the first sealing member 240 and the upper surfaces of the conductive posts 166. The first upper insulation layer 420a may include a polymer, a dielectric layer, etc. For example, the first upper insulation layer 420a may include a photosensitive insulation layer such as a photo imageable dielectric (PID).

The first upper insulation layer 420a may be formed by, e.g., a vapor deposition process, a spin coating process, etc. Due to a stress caused by a difference between thermal expansion coefficients of the first upper insulation layer 420a and the conductive posts 166, an adhesion characteristic of the interface between the upper surfaces of the conductive posts 166 and the first upper insulation layer 420a may not be effective. However, the upper surfaces of the conductive posts 166 may include the second uneven portion 166b, and the upper surfaces of the conductive posts 166 may have the second arithmetic mean roughness. By the second uneven portion 166b of the upper surfaces of the conductive posts 166, the adhesion property between the upper surfaces of the conductive posts 166 and the first upper insulation layer 420a may be improved. Thus, the delamination between the upper surfaces of the conductive posts 166 and the first upper insulation layer 420a may be reduced.

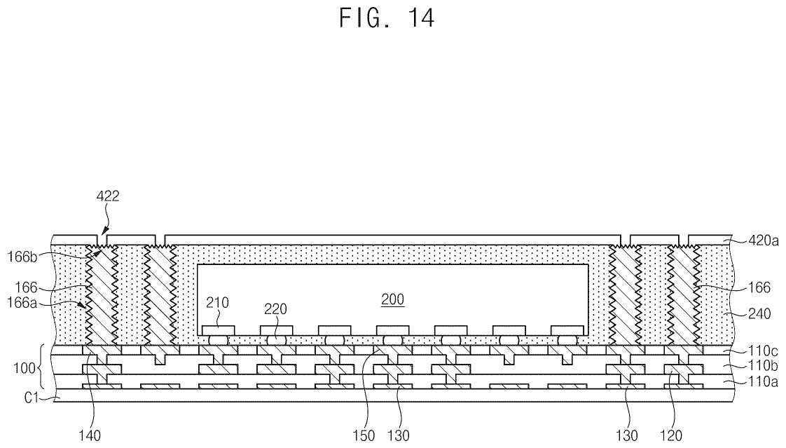

Referring to FIG. 14, the first upper insulation layer 420a may be patterned by a photolithography process to form fourth openings 422 exposing the upper surfaces of the conductive posts 166, respectively. At least a portion of the upper surfaces of the conductive posts 166 may be exposed by bottom surfaces of the fourth openings 422.

In order to form the fourth openings 422, an exposure process of a portion of the first upper insulation layer 420a may be performed. When the roughness of the upper surfaces of the conductive posts 166 facing an exposing portion of the first upper insulation layer 420a is relatively great, the fourth openings 422 may not be formed normally in the first upper insulation layer 420a due to light scattering in the exposure process. However, the roughness of the upper surfaces of the conductive posts 166 may have the second arithmetic mean roughness, such that the fourth openings 422 may be normally formed in the first upper insulation layer 420a by the exposure process.

In one or more embodiments, a portion of the upper surfaces of the conductive posts 166 may be exposed by the fourth openings 422 of the first upper insulation layer 420a, and a remaining portion of the upper surfaces of the conductive posts 166 may not be exposed by the fourth openings 422 of the first upper insulation layer 420a. Accordingly, a first portion of the lower surface of the first upper insulation layer 420a may contact the upper surface of the conductive post 166, and a second portion other than the first portion of the first upper insulation layer 420a may contact the upper surface of the first sealing member 240.

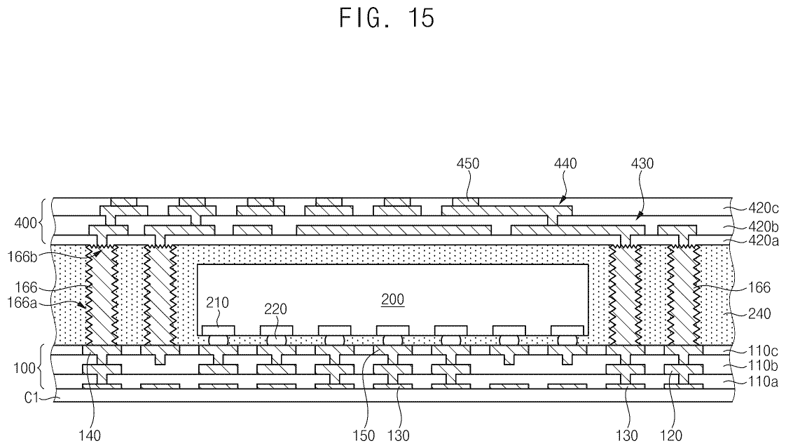

Referring to FIG. 15, after forming a seed layer on the surfaces of the conductive posts 166 exposed by the fourth openings 422 and within the fourth openings 422, the seed layer may be patterned. An electroplating process may be performed to form a first upper redistribution layer 430 including a metal. The first upper redistribution layer 430 may include a first via contact contacting the upper surface of the conductive post 166 and a first upper wiring on the first via contact.

After forming a second upper insulation layer 420b on the first upper insulation layer 420a and the first upper redistribution layer 430, the second upper insulation layer 420b may be patterned to form fifth openings exposing at least a portion of the first upper wiring. Thereafter, a second upper redistribution layer 440 may be formed on the second upper insulation layer 420b to fill the fifth openings. The second upper redistribution layer 440 may include a second via contact contacting the first upper redistribution layer 430 and a second upper wiring on the second via contact.

Third bonding pads 450 may be formed on the second upper redistribution layer 440.

The third bonding pads 450 may be disposed at an area where the upper package H is to be disposed.

Thereafter, a third upper insulation layer 420c may be formed on the second upper redistribution layer 440 to fill a space between the third bonding pads 450.

The upper redistribution layer structure 400 and the third bonding pad 450 may be a backside redistribution layer BRDL of the fan out package. The upper surface of the third bonding pad 450 may be exposed by the third upper insulation layer 420c.

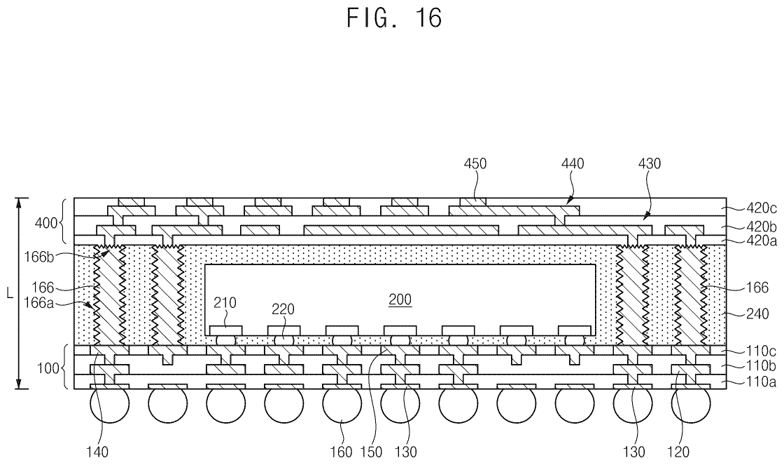

Referring to FIG. 16, the carrier substrate C1 may be removed so that a lower surface of the lower redistribution layer structure 100 may be exposed.

External connection members 500 electrically connected to the lower redistribution layers 120 may be formed on the lower pads 130 of the lower redistribution layer structure 100. The external connection members 500 may include, e.g., solder balls, conductive bumps, etc.

Thereafter, the lower redistribution layer structure 100 may be separated into individual lower redistribution layer structures 100 by a sawing process. Accordingly, a lower package L including the first sealing member 240, the lower redistribution layer structure 100 on the lower surface of the first sealing member 240, the lower semiconductor chip 200 in the first sealing member 240, and the upper redistribution layer structure 400 on the upper surface of the first sealing member 240 may be formed.

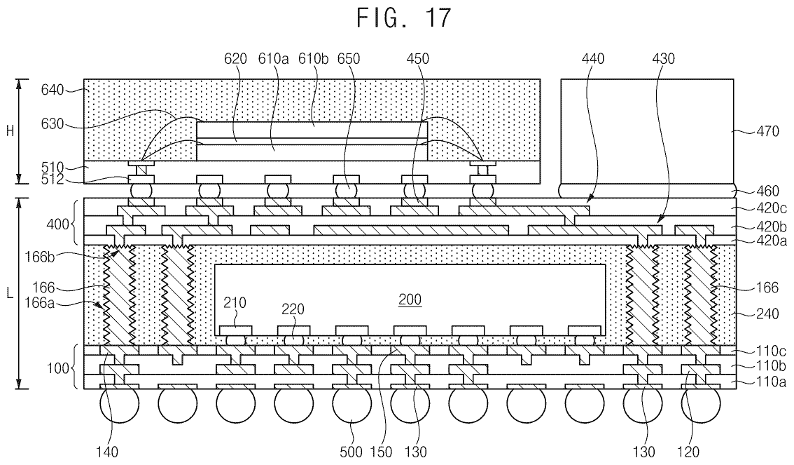

Referring to FIG. 17, a thermal interface material layer 460 may be formed on a portion of the lower package L. In addition, a heat dissipation structure 470 may be attached on the thermal interface material layer 460.

In one or more embodiments, the thermal interface material layer 460 may include grease or a thermosetting resin layer. The thermal interface material layer 460 may further include filler particles dispersed within the thermosetting resin layer. The filler particles may include a metal powder having high thermal conductivity, or a graphene powder. As another example, the filler particles may include at least one of silica, alumina, zinc oxide, and boron nitride.

The heat dissipation structure 470 may include a metal. For example, the heat dissipation structure 470 may include copper, and the upper surface of the copper may be covered with gold, silver, or nickel.

The heat dissipation structure 470 may dissipate heat generated in a process of operating the lower semiconductor chip 200 included in the lower package L to the outside. As the heat dissipation structure 470 is provided, a deterioration of the semiconductor chips in the semiconductor package due to heating of the semiconductor chips may be decreased.

Thereafter, the upper package H may be bonded on the lower package L.

In one or more embodiments, the upper package H may include a package substrate 510, at least one upper semiconductor chip 610a and 610b mounted on the package substrate 510, and the second sealing member 640 provided on and covering the upper semiconductor chips 610a and 610b disposed on the package substrate 510 and the upper semiconductor chips 610a and 610b. The upper package H may further include bonding wires 630 for connecting the upper semiconductor chips 610a and 610b and the package substrate 510 to each other.

In the upper package H, a plurality of upper semiconductor chips 610a, 610b may be sequentially stacked on the package substrate 510 using adhesive members 620. The bonding wires 630 may connect between the upper semiconductor chips 610a and 610b and the fourth bonding pads 512 of the package substrate 510.

Although the upper package H includes the bonding wires 630 and stacked two semiconductor chips 610a and 610b, the number of the semiconductor chip included in the upper package H are not limited thereto. Further, a mounting method of the upper package H is not limited thereto.

A conductive connection member 650 may be formed on the third bonding pad 450 of the lower package L, and an upper package H may be bonded on the conductive connection member 650.

The conductive connection members 650 may include, e.g., solder balls, conductive bumps, etc. The conductive connection member 650 may be interposed between the third bonding pad 450 of the upper redistribution layer structure 400 and the fourth bonding pad 516 of the package substrate 510. Therefore, the lower package L and the upper package H may be electrically connected to each other by the conductive connection members 650.

As described above, a semiconductor package may be manufactured.

According to the above processes, the adhesion property between the sidewalls of the conductive posts 166 and the first sealing member 240 may be increased, and thus the delamination between the sidewalls of the conductive posts 166 and the first sealing member 240 may be decreased. In addition, the adhesion property of the interface between the upper surfaces of the conductive posts 166 and the first upper insulation layer 420a may be increased. Accordingly, the delamination between the upper surfaces of the conductive posts 166 and the first upper insulation layer 420a and a cracking of the first upper insulation layer 420a may be decreased. Therefore, the semiconductor package may have improved reliability.

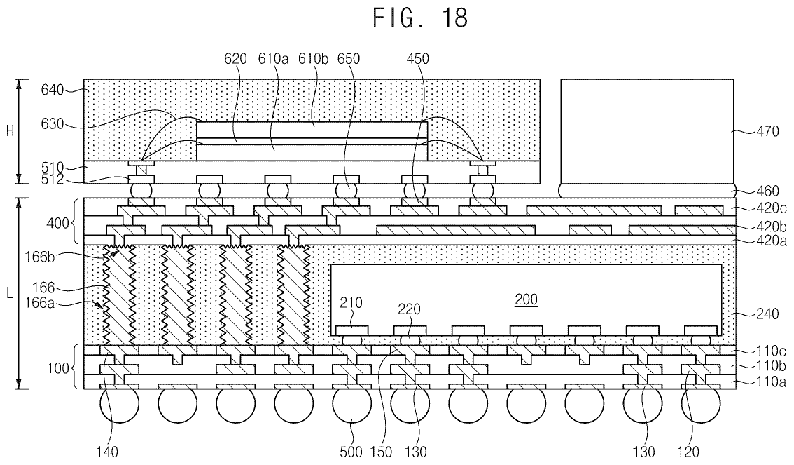

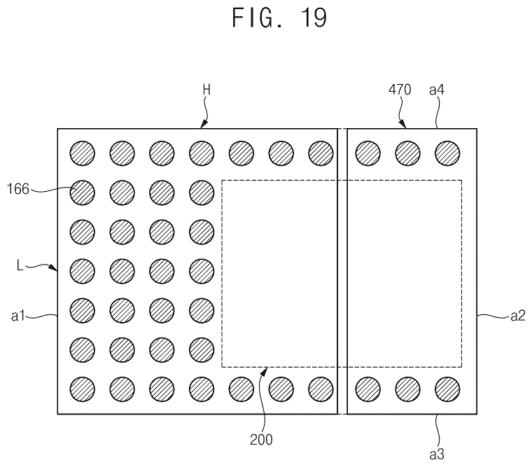

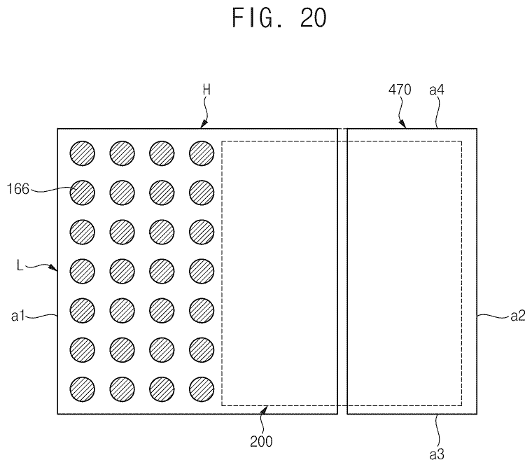

FIG. 18 is a cross-sectional view illustrating a semiconductor package according to one or more other embodiments. FIG. 19 is a plan view illustrating a semiconductor package according to one or more other embodiments. FIG. 20 is a plan view illustrating a semiconductor package according to some one or more other embodiments.

The semiconductor package shown in FIGS. 18 to 20 is the same as or similar to the semiconductor package shown in FIG. 1, except for an arrangement of the conductive post and the lower semiconductor chip. Therefore, repeated descriptions may be omitted.

Referring to FIGS. 18 and 19, a lower redistribution layer structure 100 may include a first side a1, a second side a2, a third side a3 and a fourth side a4 at edges thereof. The first side a1 and the second side a2 may opposite to each other, and the third side a3 and the fourth side a4 may opposite to each other.

A lower semiconductor chip 200 may be disposed on an upper surface adjacent to the second side a2 of the lower redistribution layer structure 100. A distance between the lower semiconductor chip 200 and the first side a1 may be greater than a distance between the lower semiconductor chip 200 and the second side a2. The distance between the lower semiconductor chip 200 and the second side a2 may be less than a diameter of an upper surface of the conductive post 166. Therefore, the conductive posts 166 may not be disposed on the lower redistribution layer structure 100 between the lower semiconductor chip 200 and the second side a2.

The conductive posts 166 may be arranged on the lower redistribution layer structure 100 at least between the lower semiconductor chip 200 and the first side a1.

In one or more embodiments, as shown in FIG. 19, the conductive posts 166 may be arranged between the lower semiconductor chip 200 and the first side a1, between the lower semiconductor chip 200 and the third side a3, and between the lower semiconductor chip 200 and the fourth side a4, respectively, but not included between the lower semiconductor chip 200 and the second side a2.

In one or more embodiments, as shown in FIG. 20, the conductive posts 166 may be arranged only between the lower semiconductor chip 200 and the first side a1, but not between the lower semiconductor chip 200 and the second side a2, the third side a3, and the fourth side a4, respectively.

The first uneven portion 166a may be formed on sidewalls of the conductive posts 166, and the second uneven portion 166b may be formed on upper surfaces of the conductive posts 166. The first uneven portion 166a may correspond to sidewalls of the conductive posts 166, and the second uneven portion 166b may correspond to upper surfaces of the conductive posts 166. The sidewalls of the conductive posts 166 may have a first arithmetic mean roughness Ra. In one or more embodiments, the first arithmetic mean roughness may be in a range of about 0.2 μm to about 0.25 μm. The upper surfaces of the conductive posts 166 may have a second arithmetic mean roughness less than the first arithmetic mean roughness. In one or more embodiments, the second arithmetic mean roughness may be in the range of about 0.05 μm to about 0.1 μm.

An upper package H may be disposed on the upper redistribution layer structure 400. At least a portion of the upper package H may be disposed so as to face the conductive posts 166 disposed between the lower semiconductor chip 200 and the first side a1.

In this case, a region where the conductive posts 166 and the upper package H overlap each other may increase, so that a layout design of the upper redistribution layer structure 400 may be facilitated.

A heat dissipation structure 470 may be stacked on the upper redistribution layer structure 400. The heat dissipation structure 470 may be spaced apart from the upper package H.

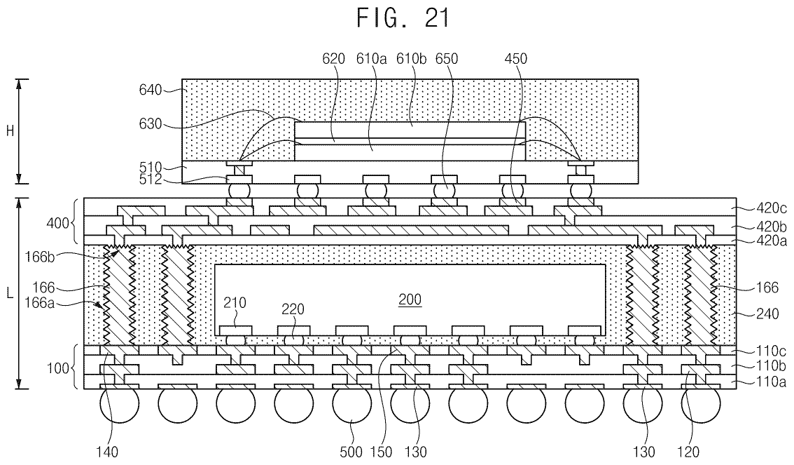

FIG. 21 is a cross-sectional view illustrating a semiconductor package according to one or more other embodiments.

The semiconductor package shown in FIG. 21 may be the same as or similar to the semiconductor package shown in FIG. 1, except that the heat dissipation structure is not included. Therefore, repeated descriptions may be omitted.

Referring to FIG. 21, an upper package H may be disposed on an upper redistribution layer structure 400. The upper package H may be disposed so that electrical connection with the upper package H and the upper redistribution layer structure 400 is facilitated. For example, the upper package H may be disposed at a central portion of the upper surface of the upper redistribution layer structure 400.

In one or more embodiments, a conductive connection member 650 may be between the upper redistribution layer structure 400 and the upper package H.

As described above, in the semiconductor package, the first uneven portion may be formed on the sidewalls of the conductive posts, and the second uneven portion having a roughness less than a roughness of the first uneven portion may be formed on the upper surfaces of the conductive posts. Accordingly, the adhesion property between the sidewalls of the conductive posts and the first sealing member may be increased. In addition, the adhesion property between the upper surfaces of the conductive posts and the first upper insulation layer may be increased. Accordingly, the delamination between the sidewall of the conductive post and the first sealing member may be decreased. In addition, the delamination between the upper surfaces of the conductive posts and the first upper insulation layer may be decreased, and a crack of the first upper insulation layer adjacent to the upper surfaces of the conductive posts may be decreased. Accordingly, the semiconductor package may have improved reliability.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a lower redistribution layer structure comprising a lower redistribution layer;
a lower semiconductor chip on the lower redistribution layer structure, the lower semiconductor chip connected to the lower redistribution layer;
a sealing member on the lower semiconductor chip and the lower redistribution layer structure;
a conductive post penetrating the sealing member, the conductive post connected to the lower redistribution layer; and
an upper redistribution layer structure on an upper surface of the sealing member and an upper surface of the conductive post, the upper redistribution layer structure comprising an upper insulation layer and an upper redistribution layer,
wherein a sidewall of the conductive post has a first uneven portion, and the upper surface of the conductive post has a second uneven portion, a roughness of the second uneven portion being different from a roughness of the first uneven portion.

2. The semiconductor package of claim 1, wherein an arithmetic mean roughness of the second uneven portion is less than an arithmetic mean roughness of the first uneven portion.

3. The semiconductor package of claim 1, wherein an arithmetic mean roughness of the first uneven portion is in a range of 0.2 μm to 0.25 μm, and an arithmetic mean roughness of the second uneven portion is in a range of 0.05 μm to 0.1 μm.

4. The semiconductor package of claim 1, wherein the upper redistribution layer comprises a via contact and a wiring line.

5. The semiconductor package of claim 4, wherein a portion of the upper surface of the conductive post contacts the via contact at a lowermost portion of the upper redistribution layer structure, and a remaining portion of the upper surface of the conductive post contacts the upper insulation layer of the upper redistribution layer structure.

6. The semiconductor package of claim 1, wherein the upper insulation layer of the upper redistribution layer structure comprises a photosensitive insulation layer.

7. The semiconductor package of claim 1, the conductive post comprises copper.

8. The semiconductor package of claim 1, the sidewall of the conductive post contacts the sealing member.

9. The semiconductor package of claim 1, the sealing member comprises an epoxy mold compound (EMC).

10. The semiconductor package of claim 1, further comprising:
an upper semiconductor package on the upper redistribution layer structure, the upper semiconductor package being connected to the upper redistribution layer structure; and
a heat dissipation structure on the upper redistribution layer structure.

11. A semiconductor package, comprising:
a lower redistribution layer structure comprising a lower insulation layer, a lower redistribution layer, and a bonding pad;
a lower semiconductor chip on the lower redistribution layer structure, the lower semiconductor chip being connected to the lower redistribution layer;
a sealing member on the lower semiconductor chip and the lower redistribution layer structure;
conductive post penetrating the sealing member and contacting the bonding pad of the lower redistribution layer, the conductive post being spaced apart from the lower semiconductor chip;
an upper redistribution layer structure on an upper surface of the sealing member and an upper surface of the conductive post, and the upper redistribution layer structure comprising an upper insulation layer and an upper redistribution layer, the upper redistribution layer being connected to the conductive post;
an upper semiconductor package on the upper redistribution layer structure, the upper semiconductor package being connected to the upper redistribution layer structure; and
a heat dissipation structure on the upper redistribution layer structure,
wherein a sidewall of the conductive post has a first uneven portion, and the upper surface of the conductive post has a second uneven portion, a roughness of the second uneven portion being different from a roughness of the first uneven portion.

12. The semiconductor package of claim 11, wherein an arithmetic mean roughness of the second uneven portion is less than an arithmetic mean roughness of the first uneven portion.

13. The semiconductor package of claim 11, wherein an arithmetic mean roughness of the first uneven portion is in a range of 0.2 μm to 0.25 μm, and an arithmetic mean roughness of the second uneven portion is within a range of 0.05 μm to 0.1 μm.

14. The semiconductor package of claim 11, wherein the upper redistribution layer comprises a via contact and a wiring line, and a portion of the upper surface of the conductive post contacts the via contact at a lowermost portion of the upper redistribution layer structure, and a remaining portion of the upper surface of the conductive post contacts the upper insulation layer of the upper redistribution layer structure.

15. The semiconductor package of claim 11, the conductive post comprises copper.

16. The semiconductor package of claim 11, the sidewall of the conductive post contacts the sealing member.

17. The semiconductor package of claim 11, the upper insulation layer at a lowermost portion of the upper redistribution layer structure contacts the upper surface of the conductive post and the upper surface of the sealing member.

18. A semiconductor package, comprising:
a lower redistribution layer structure comprising a lower insulation layer and a lower redistribution layer;
an upper redistribution layer structure being spaced apart from the lower redistribution layer structure, the upper redistribution layer structure comprising an upper insulation layer and an upper redistribution layer; and
a conductive post between the lower redistribution layer structure and the upper redistribution layer structure,
wherein a sidewall of the conductive post has a first uneven portion, and the upper surface of the conductive post has a second uneven portion, a roughness of the second uneven portion being different from a roughness of the first uneven portion.

19. The semiconductor package of claim 18, further comprising a sealing member filling a space between the lower redistribution layer structure and the upper redistribution layer structure,
wherein the first uneven portion of the sidewall of the conductive post contacts the sealing member, and the second uneven portion of the upper surface of the conductive post contacts the upper redistribution layer and the upper insulation layer.

20. The semiconductor package of claim 18, wherein an arithmetic mean roughness of the first uneven portion is in a range of 0.2 μm to 0.25 μm, and an arithmetic mean roughness of the second uneven portion is in a range of 0.05 μm to 0.1 μm.
